(19) United States
(12) Patent Application Publication
(10) Pub. No.: US 2008/0268597 A1
(43) Pub. Date: Oct. 30, 2008

(54) TECHNIQUE FOR ENHANCING DOPANT ACTIVATION BY USING MULTIPLE SEQUENTIAL ADVANCED LASER/FLASH ANNEAL PROCESSES

(76) Inventors: Andy Wei, Dresden (DE); Thomas Feudel, Radebeul (DE); Casey Scott, Dresden (DE)

Correspondence Address: WILLIAMS, MORGAN & AMERSON, 10333 RICHMOND, SUITE 1100, HOUSTON, TX, 77042, US

(21) Appl. No.: 11/964,211

(22) Filed: Dec. 26, 2007

(30) Foreign Application Priority Data
Apr. 30, 2007 (DE) 10 2007 020 261.1

(51) Int. Cl. H01L 21/30; H01L 21/336

(52) U.S. Cl. 438/275; 438/308; 257/E21.211; 257/E21.409

(57) ABSTRACT

By performing multiple radiation-based anneal processes on the basis of less critical process parameters, the overall risk for creating anneal-induced damage, such as melting of gate portions, may be substantially avoided while nevertheless the respective degree of dopant activation may be enhanced for each individual anneal process. Consequently, the sheet resistance of advanced transistor devices may be reduced with a decreasing number of sequential anneal processes.

### BACKGROUND OF THE INVENTION

1. Field of the Invention

The present disclosure generally relates to the fabrication of integrated circuits, and, more particularly, to the fabrication of highly sophisticated field effect transistors, such as MOS transistor structures, requiring highly doped shallow junctions in combination with a low series resistance.

2. Description of the Related Art

The manufacturing process for integrated circuits continues to improve in several ways, driven by the ongoing efforts to scale down the feature sizes of the individual circuit elements. Presently, and in the foreseeable future, the majority of integrated circuits are and will be based on silicon devices due to the high availability of silicon substrates and due to the well-established process technology that has been developed over the past decades. A key issue in developing integrated circuits of increased packing density and enhanced performance is the scaling of transistor elements, such as MOS transistor elements, to provide the great number of transistor elements that may be necessary for producing modern CPUs and memory devices. One important aspect in manufacturing field effect transistors having reduced dimensions is the reduction of the length of the gate electrode that controls the formation of a conductive channel separating the source and drain regions of the transistor. The source and drain regions of the transistor element are conductive semiconductor regions including dopants of an inverse conductivity type compared to the dopants in the surrounding crystalline active region, e.g., a substrate or a well region.

Although the reduction of the gate length is necessary for obtaining smaller and faster transistor elements, it turns out, however, that a plurality of issues are additionally involved to maintain proper transistor performance for a reduced gate length. One challenging task in this respect is the provision of shallow junction regions, at least at the area in the vicinity of the channel region, i.e., source and drain extension regions, which nevertheless exhibit a high conductivity so as to minimize the resistivity in conducting charge carriers from the channel to a respective contact area of the drain and source regions. The requirement for shallow junctions having a high conductivity is commonly met by performing an ion implantation sequence so as to obtain a high dopant concentration having a profile that varies laterally and in depth. The introduction of a high dose of dopants into a crystalline substrate area, however, generates heavy damage in the crystal structure, and therefore one or more anneal cycles are typically required for activating the dopants, i.e., for placing the dopants at crystal sites, and to cure the heavy crystal damage. However, the electrically effective dopant concentration is limited by the ability of the anneal cycles to electrically activate the dopants. This ability in turn is limited by the solid solubility of the dopants in the silicon crystal and the temperature and duration of the anneal process that are compatible with the process requirements. Moreover, besides the dopant activation and the curing of crystal damage, dopant diffusion may also occur during the annealing, which may lead to a loss of dopant atoms in the extension regions, thereby “blurring” the dopant profile. Thus, on the one hand, a high anneal temperature may be desirable in view of a high degree of dopant activation and re-crystallization of implantation-induced lattice damage, while, on the other hand, the duration of the anneal process should be short in order to restrict the degree of dopant diffusion, which may reduce the dopant gradient at the respective PN junctions and also reduce the overall conductivity due to reducing the averaged dopant concentration. Furthermore, very high temperatures during the anneal process may negatively affect the gate insulation layer, thereby reducing the reliability thereof. That is, high anneal temperatures may degrade the gate insulation layer and thus may influence the dielectric characteristics thereof, which may result in increased leakage currents, reduced breakdown voltage and the like. Therefore, for highly advanced transistors, the positioning, shaping and maintaining of a desired dopant profile are important properties for defining the final performance of the device, since the overall series resistance of the conductive path between the drain and source contacts may represent a dominant part for determining the transistor performance.

Recently, advanced anneal techniques have been developed in which extremely high temperatures may be achieved at a surface portion of the substrate, thereby providing sufficient energy to the atoms for activating the dopants and re-crystallizing lattice damage, wherein, however, the duration of the treatment is short enough to substantially prevent a significant diffusion of the dopant species and other impurities contained in the carrier material. Respective advanced anneal techniques are typically performed on the basis of radiation sources that are configured to provide light of appropriate wavelength that may be efficiently absorbed in upper portions of the substrate and any components formed thereon, wherein the effective duration of the irradiation may be controlled to a desired small time interval, such as a few milliseconds and significantly less. For instance, respective flash lamp exposure sources are available, which provide light of a defined wavelength range resulting in a surface-near heating of material, thereby providing the conditions for short range motions of the respective atoms in the materials provided near the surface of the carrier material. In other cases, laser radiation may be used, for instance, in the form of short laser pulses or a continuous beam that may be scanned across the substrate surface on the basis of an appropriate scan regime in order to obtain the desired short term heating at each point on the substrate. Thus, contrary to traditional rapid thermal anneal (RTA) processes, in which frequently the entire carrier material may be heated to a desired temperature, the radiation-based advanced anneal techniques create non-equilibrium conditions wherein a high amount of power is supplied within extremely short time intervals, thereby providing the required extremely high temperatures at a very thin surface layer, while the remaining material of the substrate may remain substantially unaffected by the energy deposition during the anneal process. Thus, in advanced manufacturing regimes, traditional RTA processes may frequently be replaced by advanced radiation-based anneal processes in order to obtain a high degree of dopant activation and re-crystallization in drain and source regions while not unduly contributing to dopant diffusion, which may be advantageous in terms of a steep dopant gradient at the respective PN junctions. However, in order to obtain a high degree of dopant activation, typically an increased amount of energy may have to be provided within a desired short time interval, which may be necessary for maintaining the diffusion activity at a low level, wherein, however, problems may evolve with respect to damage in device areas other than the drain and source regions, as will be explained in more detail with reference to FIGS. 1a-1c.

FIG. 1a schematically illustrates a cross-sectional view of a transistor device 100 in an advanced manufacturing stage. The transistor 100 may represent any type of sophisticated field effect transistor, as is typically used in sophisticated integrated circuits, such as micro-processors, storage chips, ASICs (application specific ICs) and the like. The transistor 100 comprises a substrate 101 which may represent any appropriate carrier material for forming thereon an appropriate semiconductor layer 102 in and above which respective circuit components, such as the transistor 100, are to be formed. The substrate 101 may represent a bulk semiconductor substrate, such as a silicon substrate, or the carrier material may be made of or may comprise an insulating material that may form a dielectric barrier between the semiconductor layer 102 and any other lower lying device regions. For instance, the substrate 101, in combination with the semiconductor layer 102, may represent a semiconductor-on-insulator (SOI) configuration when a buried insulating layer or a fully insulating material is provided below the semiconductor layer 102. Typically, the semiconductor layer 102 may represent a silicon-based material, since presently and in the near future sophisticated semiconductor devices with high integration density are and will be manufactured on the basis of silicon-based material. A gate electrode 105, which is typically comprised of polysilicon, is formed above the semiconductor layer 102 and substantially defines a channel region 103, which is located below the gate electrode 105 and is separated therefrom by a gate insulation layer 106. The gate electrode 105 comprises sidewalls on which a respective spacer structure 107 is formed, which may include a plurality of individual spacer elements and liners (not shown). Furthermore, drain and source regions 104, i.e., highly doped semiconductor regions, are formed adjacent to the channel region 103, wherein typically so-called extension regions 104E may be provided next to the channel region 103 to provide respective shallow PN junctions with a desired dopant gradient at the transition area connecting to the channel region 103.

Typically, the transistor device 100 may be formed on the basis of the following processes. After providing the substrate 101 having formed thereon the semiconductor layer 102, respective isolation structures (not shown), such as shallow trench isolations (STI) and the like, may be formed to define appropriately sized active areas in which one or more circuit components may be formed, such as the transistor 100. For this purpose, sophisticated lithography, etch, deposition and planarization techniques may be used. Next, the basic doping in the corresponding active regions is defined on the basis of well-established ion implantation processes, wherein respective resist masks may be used to prevent the incorporation of unwanted dopant species into certain device areas. Thereafter, appropriate materials for the gate electrode 105 and the gate insulation layer 106 may be provided, for instance, by oxidation and/or deposition for the gate insulation layer 106 and deposition of the material of the gate electrode 105, followed by advanced lithography and etch techniques in order to appropriately define the lateral dimensions of the gate electrode 105. For sophisticated applications, a gate length, i.e., the horizontal extension of the gate electrode 105 in FIG. 1a, may be 100 nm and significantly less. Thereafter, respective spacer elements of the structure 107 may be formed to act, in combination with the gate electrode 105, as an implantation mask when performing a plurality of implantation processes, such as amorphization implantations, halo implantations, drain and source extension implantations and the like, in order to obtain the desired lateral and vertical dopant profile for the drain and source regions 104 and the extension regions 104E.

As previously explained, during the various implantation processes, the crystal lattice in the semiconductor layer 102 may be damaged, for instance intentionally, by performing pre-amorphization processes, and hence the corresponding highly damaged or amorphized portions may have to be re-crystallized, while also activating the dopant species, i.e., placing as many dopant atoms as possible at respective lattice sites so that the corresponding atoms may act as donators or acceptors of electrons. During a corresponding thermal treatment, increased motion of the respective dopant species is typically not desired, since the diffusion of the dopant atoms may result in a reduced gradient at the respective PN junctions, thereby possibly compromising the desired transistor function. Consequently, in advanced applications, anneal techniques may be used which provide the required high temperatures within the semiconductor layer 102, while the duration of the corresponding treatment may be restricted to extremely short time intervals, such as milliseconds, microseconds and even less, thereby substantially not allowing a significant diffusion activity of the dopant species. Hence, the radiation-based anneal process 108 is performed, for instance, on the basis of flash lamp irradiation, laser irradiation, wherein light of a specified wavelength range or a single wavelength is provided with high energy density onto the device 100, for instance in a substantially global exposure or locally by scanning a corresponding radiation beam across the substrate 101, thereby achieving temperatures of up to 1200° C. and even more at surface-near areas in the substrate 101 and providing the required conditions for re-crystallization and activation. Although, on the other hand, relatively high energy densities may be used, the total energy delivered to the substrate 101 is moderately low, thereby substantially not resulting in a significant temperature increase in lower lying device areas. For instance, the back side of the substrate 101 may remain at moderately low temperatures, such as 50-100° C. In order to obtain a desired high degree of dopant activation, the respective flash-power settings or laser energy densities are selected to moderately high values, since an increased degree of dopant activation results in a reduced series resistance of the drain and source regions 104, including the extension regions 104E. However, the corresponding energy may also be absorbed in the gate electrode 105 and the corresponding spacer structure 107, thereby resulting in respective damage.

FIG. 1b schematically illustrates a top view of the device 100 after performing the radiation-based anneal process 108 at moderately high energy densities in order to obtain a high degree of dopant activation. The degree of energy absorption may significantly depend on the surface topography and local conditions above the substrate 101, which may therefore result in increased energy absorption at non-desired positions, such as the gate electrode 105. For instance, as indicated in FIG. 1b, extended areas of the gate electrode 105 may melt during the radiation-based anneal process 108, for example, at the portion 105A, thereby resulting in non-functional circuit elements.

FIG. 1c schematically illustrates a cross-sectional view of the portion 105A, wherein the configuration of the gate electrode 105 and the spacer structure 107 may be significantly distorted or may even be completely melted away during the anneal process 108.

Consequently, although advanced anneal processes using flash lamp-based or laser-based radiation sources may be highly effective in activating dopants substantially without generating a significant diffusion activity of the dopant atoms, conventional techniques as previously described may suffer from significant device damage when using appropriately high energy densities during the short time irradiation process. Consequently, the present disclosure is related to various techniques that may solve or at least reduce some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein is directed to a technique for enhancing the transistor performance by performing radiation-based anneal processes to obtain a desired high degree of dopant activation while not unduly contributing to diffusion of the dopant atoms. For this purpose, a plurality of short time radiation-based anneal processes may be performed, wherein each individual anneal step may be performed at appropriately selected energy and power settings so as to substantially not cause any damage in sensitive device areas, such as gate electrodes of transistor elements. It has been recognized that a series of radiation-based anneal processes may gradually increase the degree of dopant activation, while, on the other hand, each individual step may have a moderately low probability for creating respective device damage. Consequently, a desired reduction in series resistance in transistor devices may be obtained, while not contributing to enhanced device damage and undue dopant diffusion.

One illustrative method disclosed herein comprises annealing drain and source regions of a first transistor provided on a substrate by performing a first radiation-based anneal process, wherein the first radiation-based anneal process results in irradiating the drain and source regions for a first irradiation time that is less than approximately 0.1 second. The method further comprises annealing the drain and source regions of the first transistor by performing a second radiation-based anneal process, wherein the second radiation-based anneal process results in an irradiation of the drain and source regions for a second irradiation time of less than approximately 0.1 seconds.

A further illustrative method disclosed herein comprises forming drain and source regions of a first transistor device by performing a plurality of implantation processes for incorporating a dopant species in the drain and source regions. Moreover, the method comprises activating the dopant species in the drain and source regions in the first transistor by performing a plurality of radiation-based anneal processes, each of which irradiates the drain and source regions of the first transistor for a time interval of approximately ten milliseconds or less.

In still another illustrative method disclosed herein, an extension region of a first transistor is formed above a substrate, wherein the substrate comprises a first transistor and a second transistor. Furthermore the method comprises annealing the first transistor by performing a first radiation-based anneal process and forming an extension region of a second transistor after performing the first radiation-based anneal process. Additionally, the method comprises annealing the second transistor by performing a second radiation-based anneal process.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a transistor during a conventional advanced radiation-based anneal process;

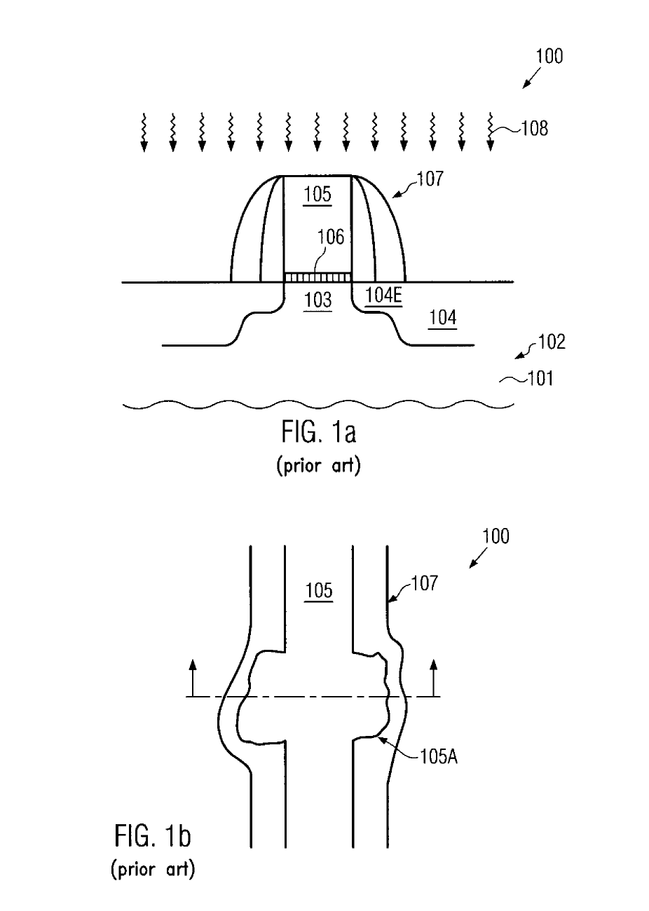

FIG. 1b schematically illustrates a top view of the transistor of FIG. 1a including a damaged portion in the gate electrode thereof;

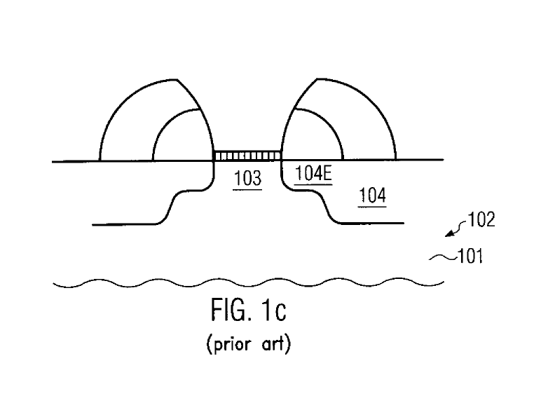

FIG. 1c schematically illustrates a cross-sectional view of the damaged portion of the gate electrode of the transistor of FIGS. 1a and 1b;

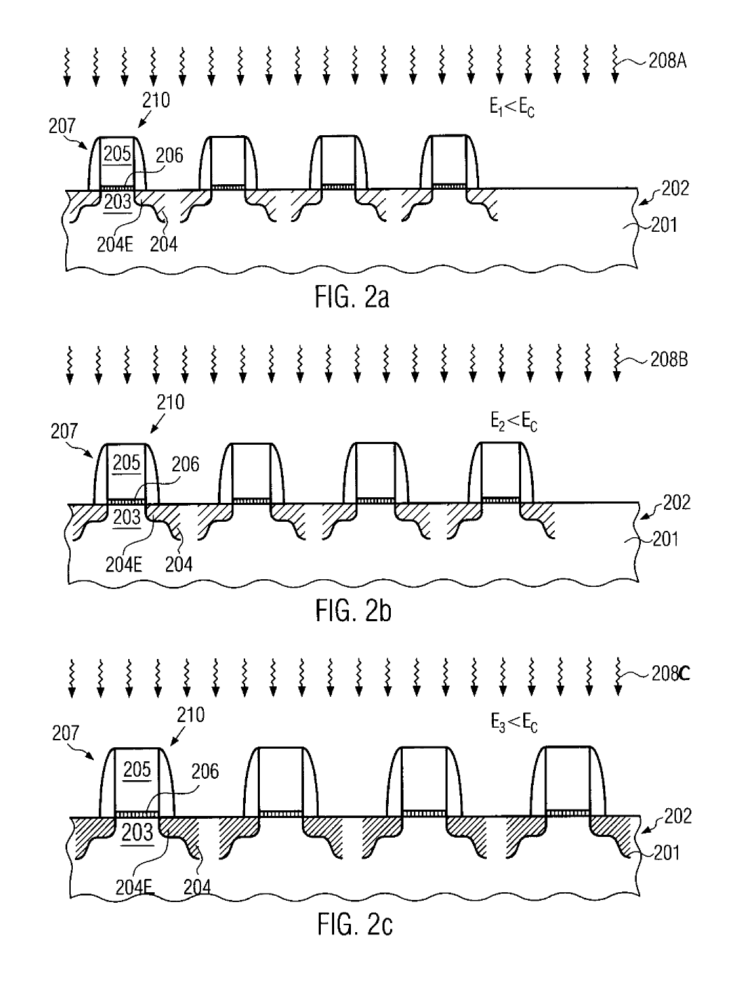

FIGS. 2a-2c schematically illustrate cross-sectional views of a semiconductor device during a sequence of radiation-based anneal processes for obtaining a high degree of dopant activation while reducing the risk of creating collateral damage in the respective gate electrodes according to illustrative embodiments;

FIG. 2d schematically illustrates a representation of experimental data indicating the successive improvement of the sheet resistance of drain and source extension regions in performing a plurality of less critical radiation-based anneal processes according to illustrative embodiments; and

FIGS. 3a-3e schematically illustrate cross-sectional views of transistor elements during various manufacturing stages, wherein respective radiation-based anneal processes are performed with less critical process parameters, wherein, in total, an enhanced degree of dopant activation may be achieved according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The subject matter disclosed herein generally relates to the formation of advanced transistor elements with critical dimensions of 100 nm and significantly less, in which the transistor performance may be significantly determined by the overall resistance of the conductive path between the drain and source contacts. That is, in particular, the sheet resistance of the shallow drain and source extension regions, which form respective PN junctions with the adjacent channel region, may play an important role in the overall transistor performance. Consequently, a high dopant concentration may typically be required, although usually somewhat lower than in the deep drain and source portions, wherein a respective dopant gradient at the PN junction may be important in view of transistor characteristics, such as switching speed and the like. Hence, it is contemplated in the techniques disclosed herein that an increased degree of dopant activation may be achieved by performing a plurality of radiation-based anneal processes in order to accumulate the desired effect of enhancing the degree of dopant activation during each individual step, while nevertheless maintaining the dopant diffusion in each individual step at a very low level. Each of the individual radiation-based anneal processes may be performed on the basis of less critical process parameters with respect to energy density irradiated on the respective locations of the semiconductor device, thereby significantly reducing the probability for creating radiation-induced damage in each individual step and thus in the entire sequence of the plurality of radiation-based anneal processes. Therefore, in some illustrative embodiments, the radiation-based anneal process may be performed so as to expose each position on the substrate to an appropriate irradiation dose, i.e., an accumulated energy per time unit, wherein, in each time interval, critical process temperatures may be avoided, for instance in the gate electrodes, while nevertheless an efficient dopant activation may occur in the drain and source regions. Furthermore, the overall irradiation time may nevertheless be maintained sufficiently low so as to suppress or reduce any undesired diffusion activity of the dopant atoms.

It should be appreciated that the principles disclosed herein are highly advantageous in the context of semiconductor devices including transistor elements having a gate length of 100 nm and less, such as 50 nm and less, since here pronounced dopant profiles at PN junctions are required while also the degree of dopant activation should be increased as much as possible in order to reduce the sheet resistance of the corresponding doped semiconductor areas. However, the techniques disclosed herein may also be efficiently applied to less critical semiconductor devices, thereby providing reduced yield losses and enhanced device uniformity. Consequently, the present disclosure should not be considered as being restricted to specific device dimensions, unless such restrictions are explicitly set forth in the description or the appended claims.

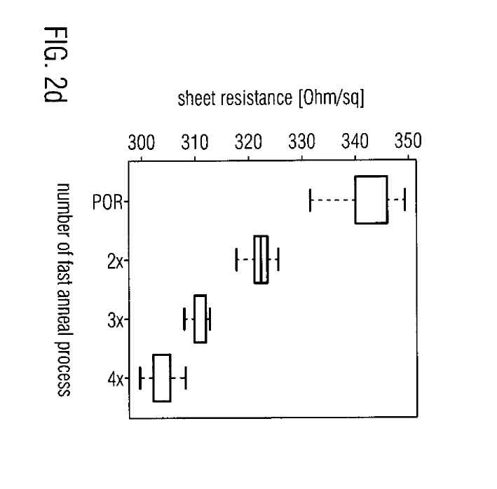

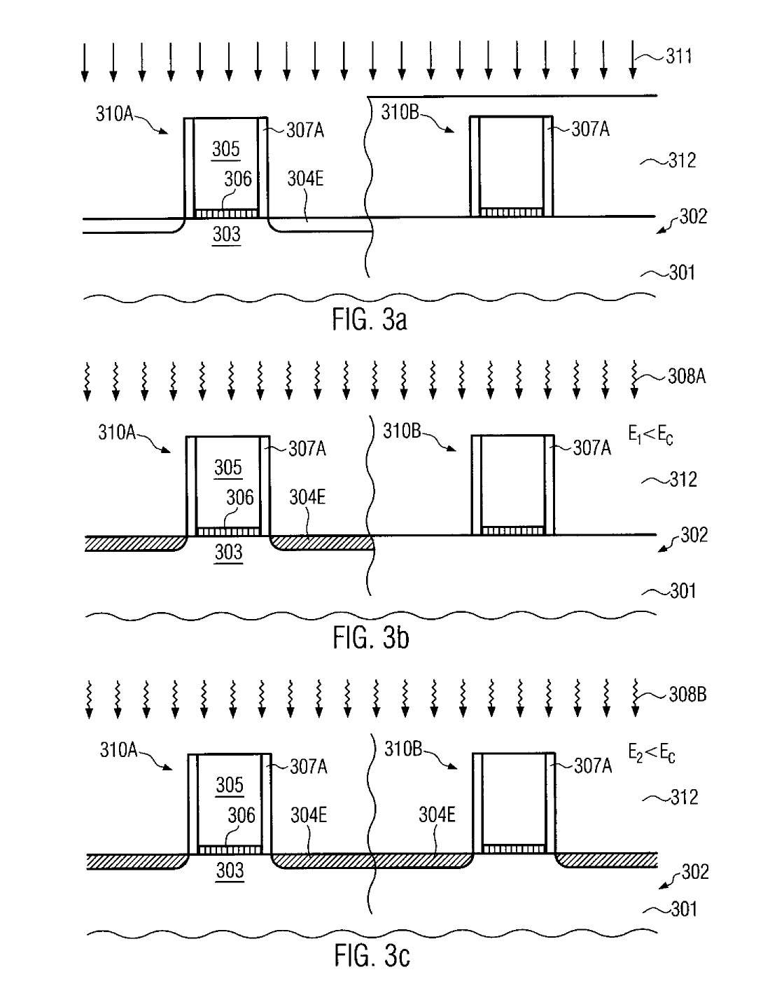

FIG. 2a schematically illustrates a cross-sectional view of a semiconductor device 200 comprising a substrate 201, which may represent any appropriate carrier material for forming thereon a semiconductor layer 202, which in turn may be comprised of any appropriate semiconductor material, such as silicon, silicon/germanium, silicon/carbon, other II-VI or III-V semiconductor compounds and the like. As previously explained, the semiconductor layer 202 may, in some illustrative embodiments, comprise a significant amount of silicon due to the fact that semiconductor devices of high integration density may be formed in volume production on the basis of silicon due to the enhanced availability and the well-established process techniques developed over the last decades. However, in other illustrative embodiments, any other appropriate semiconductor materials may be used, for instance, a silicon-based material containing other iso-electronic components, such as germanium, carbon and the like. Furthermore, the substrate 201 and the semiconductor layer 202 may define an SOI configuration, as previously explained. In and above the semiconductor layer 202, a plurality of circuit elements 210 may be formed, wherein, in the embodiment shown, a plurality of field effect transistors may be provided. In the manufacturing stage shown, each of the transistors 210 may comprise a gate electrode 205 formed on a corresponding gate insulation layer 206, which separates the gate electrode 205 from a channel region 203 defined in the semiconductor layer 202. Moreover, in some illustrative embodiments, a spacer structure 207 may be formed on sidewalls of the gate electrode 205, wherein the configuration of the spacer structure 207 may depend on process requirements. It should be appreciated that the spacer structure 207 may comprise a plurality of individual spacer elements, as previously explained, wherein, in this manufacturing stage, some of the spacer elements may have already been removed or may still have to be formed, depending on the process strategy. In one illustrative embodiment, the spacer structure 207 in this manufacturing stage may comprise a plurality of individual spacer elements as required for the definition of the vertical and lateral dopant profile in respective drain and source regions, i.e., in respective deep drain and source portions 204 and respective drain and source extension regions 204E. In other illustrative embodiments, one or more of the individual spacer elements of the structure 207 may have been removed after the formation of the respective drain and source regions 204, when the corresponding spacer elements are considered inappropriate for the further processing of the device 200.

The semiconductor device 200 as shown in FIG. 2a may be formed on the basis of the following processes. After providing the substrate 201 including the semiconductor layer 202, respective isolation structures (not shown), such as shallow trench isolations and the like, may be formed in order to define the respective active areas for one or more of the transistor elements 210, as previously explained. For instance, the transistors 210, as shown in FIG. 2a, may represent transistors of the same conductivity type, wherein some or all of the transistors 210 may be formed within the same active region. In other cases, the transistors 210 may represent transistors of different conductivity type, which may be separated by respective isolation structures (not shown). Thereafter, a corresponding doping of the one or more active regions may be performed in order to establish the required transistor base conditions, and subsequently the gate insulation layers 206 and the gate electrodes 205 may be formed on the basis of process techniques, as previously described with reference to the device 100. Next, in one illustrative embodiment, a plurality of implantation processes may be performed, for instance on the basis of respective spacer elements of the structure 207, so as to define the vertical and lateral dopant profiles of the deep drain and source portions 204 and of the extension regions 204E, wherein the respective drain and source regions for each type of transistors may be completed prior to performing a respective anneal sequence for activating dopants and re-crystallizing the damaged lattice structure.

In other illustrative embodiments, one or more of the respective implantation processes may be accompanied by an appropriately designed radiation-based anneal process, as will be described later on in more detail. In still other illustrative embodiments, during the respective implantation sequence, or thereafter, other anneal processes may be performed, for instance, at moderately low temperatures so as to maintain the respective dopant diffusion at a low level, while nevertheless initiating an efficient re-crystallization process. For instance, a heat treatment at temperatures of approximately 500-800° C. may be performed on the basis of conventional techniques, such as a lamp-based anneal process, in which the substrate 201 is substantially in thermal equilibrium while the respective temperatures are moderately low so as to maintain the diffusion activity at a moderately low level. For instance, it may be advantageous to re-crystallize the substantially amorphized areas in the drain and source regions 204 and/or in the extension regions 204E after performing the respective implantation processes on the basis of a pre-amorphization implant process, wherein, additionally, an adaptation of the respective dopant profile may be obtained when the profile as deposited may not be considered appropriate for the transistor function. That is, if a specified overlap of the extension region 204E with the gate electrode 205 may be desired, the respective extension implantation may be performed on the basis of an appropriately selected offset spacer so as to not unduly damage the gate insulation layer 206, wherein the respective overlap may then be adjusted on the basis of the thermal diffusion of the dopant species during a corresponding anneal process for also re-crystallizing damaged lattice portions. However, in this case, the respective anneal temperature may be selected moderately low, thereby obtaining a high degree of controllability of the respective diffusion activity.

In other illustrative embodiments, respective “conventional” anneal techniques may be omitted, when respective steep dopant gradients may be desired, as previously explained. After one or more of the implantation processes performed to define the deep drain and source portions 204 and the extension regions 204E, a first radiation-based anneal process 208A may be performed to activate dopants and also re-crystallize implantation-induced damage. The radiation-based anneal process 208A may be performed on the basis of a process parameter setting that provides a reduced probability for creating collateral damage in sensitive device areas, such as the gate electrodes 205 and the gate insulation layers 206. For this purpose, at least one process parameter may be selected on the basis of a predetermined threshold value, indicated as E_{C}, which may define a lower limit for causing respective damage in the gate electrode 205. For example, the energy density may be maintained below a predefined critical energy density which may have been found, for instance by experiment, to have a respective probability for inducing damage in the gate electrodes 205. A respective appropriate parameter setting, for instance based on the determination of a corresponding critical parameter value, may be accomplished on the basis of experiments and respective investigations in order to determine the corresponding damage caused by a specific energy density. For instance, different device areas, which may, for instance, correspond to different transistor elements 210, may be exposed to a different energy density during a plurality of radiation-based anneal processes which may, for instance, be accomplished by varying a respective scan speed or by otherwise locally varying the corresponding irradiated energy density. Thereafter, the respective conditions of the gate electrodes 205 may be examined, for instance on the basis of optical inspection, electron microscopy, cross-sectional analysis techniques, such as transmission electron microscopy, and the like. Based on the respective experimental data, at least one process parameter may be identified and a respective critical value E_{c} thereof may be determined in order to provide a reasonable limit for the creation of anneal-induced damage in the gate electrodes 205 and/or the gate insulation layers 206.

The radiation-based anneal process 208A may be performed on the basis of available laser-based flash-based systems. For instance, in a laser-based anneal system, an appropriate laser source may provide a continuous or a pulsed laser beam, which may be directed onto a specific device portion by means of an appropriate beam shaping system. That is, depending on the output power of the laser source, the respective beam shaping system may provide a desired specific beam shape and thus size of a corresponding device portion and the energy density supplied thereto. Typically, an appropriate scan system may be provided for generating a respective relative movement between the corresponding radiation beam and the substrate 201, wherein the corresponding scan speed may be selected so that a desired total exposure time during the anneal process 208A is obtained for each exposed device area. As previously explained, since dopant diffusion may not be desirable during the radiation-based anneal process 208A, the corresponding scan speed is typically selected such that an effective exposure to the radiation beam is restricted to extremely short time intervals in the range of 0.1 seconds and significantly less, such as 10 milliseconds, or even microseconds and less. On the other hand, the local temperature in the surface-near area of the substrate 201 may depend on the energy density, which is conventionally selected moderately high so as to obtain a high degree of dopant activation while not significantly contributing to dopant diffusion. Contrary thereto, the anneal process 208A is performed on the basis of a parameter value E_{c}, such as the energy density and the like, so as to substantially avoid undue damage in sensitive device areas, such as the gate electrodes 205, wherein an enhanced degree of dopant activation compared to conventional strategies may be obtained by performing a plurality of respective radiation-based anneal processes 208, as will be described later on.

In other illustrative embodiments, the thermal response of a respective device portion, such as a temperature obtained by contactless measurement, may be used for controlling the respective process 208A so as to maintain the anneal conditions below a critical condition which may result in increased damage of the gate electrodes 205, as previously explained. For example, the local temperature may be determined on the basis of respective contactless sensors and the respective sensor response may be correlated to respective analysis data or other experimental data that may indicate a corresponding damage created by the respective anneal conditions. Consequently, an efficient control strategy may be obtained on the basis of a respective temperature measurement, although the corresponding temperature may only represent an averaged temperature of the device portion under consideration since the local temperature and thus the respective probability for creating collateral damage in the gate electrodes 205 may vary significantly due to the difference in material composition, device topography and the like. During the anneal process 208A, the radiation may be, at least partially, absorbed and may therefore result in a respective energy, that is, kinetic energy, for the atoms in the drain and source regions 204 and the extension regions 204E so as to initiate a short range movement for reconfiguring the crystalline lattice, thereby also incorporating respective dopant atoms in respective lattice sites, resulting in a certain degree of dopant activation as is indicated by the hatched lines in the drain and source regions 204 and the extension regions 204E.

FIG. 2b schematically illustrates the semiconductor device 200 during a further radiation-based anneal process 208B that is also performed on the basis of a respective process parameter value selected to not unduly increase the probability for creating damage in the gate electrodes 205, as previously explained. That is, at least one parameter value, such as the energy density, is adjusted so as to remain below the previously determined critical energy density, thereby substantially avoiding undue damage. The radiation-based anneal process 208B may be performed, in some illustrative embodiments, on the basis of substantially the same process parameters as the process 208A, thereby providing enhanced process throughput. For instance, the process 208B may correspond to a further scan motion of the respective radiation beam across the substrate 201, after performing a first scan motion corresponding to the anneal process 208A while providing sufficient time between the two scan motions so as to dissipate the energy supplied during the first anneal process 208A into the deeper areas of the substrate 201. In this case, the second anneal process 208B may be considered as an anneal process performed under substantially the same process conditions as the first process 208A. For example, the entire substrate 201 may be scanned during the first process 208A so as to provide a first step for the dopant activation as previously explained. Thereafter, the substrate 201 may be subjected to a further scan motion across the entire substrate in order to perform the second anneal process 208B. In other illustrative embodiments, the respective scan pattern may be selected such that respective device portions, such as the transistors 210, may be sequentially scanned during the process 208A and may be subsequently scanned during the process 208B, before other device areas on the substrate 201 may be subjected to the first process 208A followed by the second process 208B. In this way, excessive motion of the substrate 201 and/or of the corresponding irradiation beam may be avoided. The respective scan areas may be selected such that, after the first process 208A, when returning the irradiation beam to the first one of the device portions previously exposed in the process 208A, a sufficient heat dissipation may have taken place prior to beginning the next scan motion.

In still other illustrative embodiments, the first and second anneal processes 208A, 208B may be performed on the basis of different process parameters or may even be performed on the basis of different types of anneal processes in order to obtain a higher degree of spectral coverage during the entirety of anneal processes to be performed on the semiconductor device 200. For example, the processes 208A, 208B may be performed such that at least one process parameter, such as irradiation time, may be varied, for instance reduced in the second process 208B, when, for instance, the heat created during the previous radiation-based process 208A may have not yet fully dissipated into the deeper areas of the substrate 201. Consequently, by appropriately reducing the irradiation time or the energy density, or both, the probability of creating respective damage in the gate electrodes 205 may also be maintained at a low level. Thus, in case of irradiation by a laser scan system, a restricted device portion may be heat-treated multiple times without excessive scan motion. In other illustrative embodiments, one or more of the radiation-based anneal processes 208A, 208B may be performed by using a flash light system, which may typically provide irradiation pulses of short duration with a moderately wide wavelength range. In this case, a more uniform energy deposition into the respective surface-near materials may be obtained, irrespective of the respective optical characteristics of the various materials exposed to the incoming radiation. In other cases, flash light-based anneal processes may be combined with laser-based anneal processes so as to combine the spectral coverage of the flash light irradiation with the laser-based irradiation, providing enhanced local and spectral resolution. For instance, respective critical process parameter values may be determined for each type of anneal process to be used, thereby reducing the risk of creating damage in each individual anneal process 208A, 208B.

FIG. 2c schematically illustrates the semiconductor device 200 during a further radiation-based anneal process 208C, which may also be performed on the basis of appropriately selected process parameters so as to reduce the risk of creating respective damage in the gate electrodes 205, the gate insulation layers 206 or any other sensitive device areas. With respect to the radiation-based anneal process 208C, the same criteria apply as previously explained for the processes 208A and 208B. Hence, the process 208C may be performed in any appropriate time-dependent manner with respect to the processes 208A, 208B, as previously explained, thereby further enhancing the degree of dopant activation, as indicated by the dense lines in the hatched drain and source regions 204 and the extension regions 204E.

FIG. 2d schematically illustrates a graph representing experimental data for the relationship between the sheet resistance of the extension regions 204E and the number of sequentially performed anneal processes 208A, 208B, 208C. The vertical axis represents the sheet resistance measured in ohm per square on the basis of appropriate measurement techniques as are well established in the art. The horizontal axis represents the number of anneal processes performed, wherein respective experimental data are obtained by performing substantially identical radiation-based anneal processes, such as the processes 208A, 208B, 208C. As is evident from FIG. 2d, the respective sheet resistance of the extension regions 204E obtained after the first radiation-based anneal process may further be reduced during each of the subsequent anneal processes, for instance resulting in a reduction of approximately 40 ohm per square after performing the fourth anneal process. Thus, the degree of dopant activation may be significantly enhanced, thereby reducing the sheet resistance of the respective doped areas while nevertheless substantially avoiding undue damage in other sensitive device areas and also maintaining the diffusion activity of the respective dopants at a low level, since the accumulated irradiation time may still be maintained within a specified time limit. For instance, each individual anneal process may be performed for a time interval of 0.1 second or significantly less, for instance for 10 milliseconds and less or 1 millisecond or less, thereby obtaining an overall short irradiation time. It should be appreciated, however, that, in other illustrative embodiments, even smaller time intervals for each individual anneal step may be used, such as several microseconds and even less. The reduced sheet resistance of the extension regions 204E and also the reduced resistance of the deep drain and source portions 204 may contribute significantly to a reduced overall resistance and thus may enhance the drive current capability of the respective transistors 210. Although the respective increase of drive current capability may not be necessarily equivalent to the respective improvement of sheet resistance, since further factors may have an influence on the overall transistor performance, such as charge carrier mobility in the channel regions 205 and the like, a significant improvement may be obtained, in particular, for highly scaled semiconductor devices.

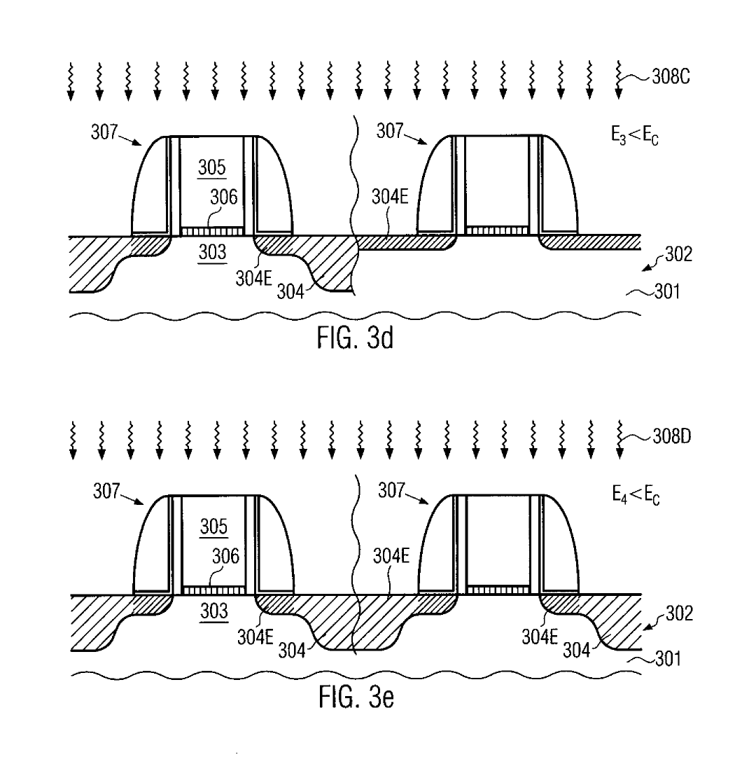

With reference to FIGS. 3a-3e, further illustrative embodiments will now be described, in which a plurality of individual radiation-based anneal processes are performed at various manufacturing stage.

FIG. 3a schematically illustrates a cross-sectional view of a semiconductor device 300 comprising a first transistor 310A and a second transistor 310B. The transistors 310A, 310B may represent transistors of different conductivity type or transistors provided in very different device areas and the like. In one illustrative embodiment, the first transistor 310A may represent an N-channel transistor, while the second transistor 310B may represent a P-channel transistor. The transistors 310A, 310B are formed above a substrate 301 having formed thereon an appropriate semiconductor layer 302. With respect to the substrate 301 and the semiconductor layer 302, the same criteria apply as previously explained with reference to the device 100 and 200. In the manufacturing stage shown, respective offset spacers 307A may be formed on sidewalls of respective gate electrodes 305, which are formed on respective gate insulation layers 306 separating the gate electrodes 305 from respective channel regions 304. Furthermore, the device 300 may be subjected to an implantation process 311 performed on the basis of a resist mask 312 in order to form a respective extension region 304E in the first transistor 310A. It should be appreciated that the implantation process 311 may be preceded by further implantation processes for providing a substantially amorphized portion in the semiconductor layer 302 adjacent to the respective channel regions 303 and for defining a halo region (not shown), if required. With respect to any manufacturing processes for forming the device 300 as shown in FIG. 3a, it may be referred to the description of the respective manufacturing processes described with reference to the devices 100 and 200. It should be appreciated that the offset spacers 307A may be formed on the basis of well-established techniques, such as the deposition of an appropriate material, such as silicon dioxide, silicon nitride, and patterning the same on the basis of an anisotropic etch process.

FIG. 3b schematically illustrates the semiconductor device 300 in an advanced manufacturing stage, in which a resist mask 312 has been removed and the device 300 is subjected to a first radiation-based anneal process 308A in order to activate the dopant, such as N-type dopants in the extension regions 304E, and also to re-crystallize, at least to a certain degree, the structure adjacent to the channel region 303 of the first transistor 310A. As previously discussed, the anneal process 308A may be performed on the basis of appropriately selected process parameters which provide a low probability of creating lattice damage in sensitive device areas, such as the gate electrodes 305 and the gate insulation layers 306. Appropriate process parameters may be obtained based on respective experiments as previously described, wherein it should be appreciated that the respective parameter limits may be different due to the different surface topography and material composition of the respective components compared to the device as shown in FIG. 2a. For example, due to the absence of respective further spacers, such as the spacer structure 207 in FIG. 2a, which may typically be comprised of silicon nitride, the optical response of the device 300 and thus the corresponding degree of energy absorption and heat dissipation may result in a different critical value for the respective radiation-based anneal process 308A. In any case, the respective process parameters may be selected such that a significant melting of the gate electrode 305 may be avoided. Hence, during the first radiation-based anneal process 308A, a significant degree of dopant activation may be achieved in the extension region 304E of the first transistor 310A, while a respective dopant concentration in the second transistor 310B, as may have previously been established so as to define the basic transistor configuration, may not be substantially affected due to the short irradiation duration, as previously explained.

FIG. 3c schematically illustrates the device 300 in a further advanced manufacturing stage. Here, a respective implantation process may have been performed to define the respective extension regions 304E in the second transistor 310B on the basis of an appropriate dopant species, such as a P-type dopant species, and subsequently the device 300 may be subjected to a second radiation-based anneal process 308B. The second process 308B may also be performed on the basis of appropriately selected process parameters so as to substantially avoid damage to the gate electrodes 305. In some illustrative embodiments, the process 308B may be performed on the basis of substantially the same process parameters as the process 308A. In other illustrative embodiments, the process parameters, such as energy density, duration and the like, may be selected differently in the process 308B so as to adapt the respective process conditions to the characteristics of the respective dopant species, which may have a different activation energy in the second transistor 310B compared to the first transistor 310A. However, irrespective of the respective process parameters, undue diffusion in the first transistor 310E may be substantially avoided, while nevertheless additionally increasing the degree of dopant activation in the corresponding extension region 304E of the first transistor 310A. Consequently, even if the second radiation-based anneal process 308B may be specifically designed with respect to the second transistor 310B, a significant additional activation of the dopants in the first transistor 310A may be achieved. It should be appreciated that, in some illustrative embodiments, the respective implantation process for incorporating the dopant species of the extension regions 304E in the second transistor 310B may be preceded by a respective pre-amorphization implantation and halo implantation, as previously described for the first transistor 310A. By performing a separate pre-amorphization implantation for each of the transistors 310A, 310B, the respective implantation process for the extension region 304E may be performed on the basis of a substantially amorphous substrate material, irrespective of the anneal process 308A.

In some illustrative embodiments, the further processing may be continued by forming respective deep drain and source portions on the basis of an appropriately designed spacer structure and subsequently activating the respective dopants in one or more anneal processes, such as radiation-based anneal processes, as previously described with respect to the device 200, thereby obtaining a high degree of dopant activation without unduly damaging the gate electrodes 305 or substantially without causing undue dopant diffusion, as previously explained. In other cases, a conventional anneal process may be used if a re-crystallization of implantation-induced damage is desired on the basis of lower temperatures and/or if a certain degree of dopant diffusion is desirable in order to appropriately adapt the transistor configuration, such as overlap of the extension regions 304E with the gate electrodes 305, as previously explained.

FIG. 3d schematically illustrates the semiconductor device 300 according to further illustrative embodiments, in which additional radiation-based anneal processes, such as a third anneal process 308C, may be performed in an intermediate stage during the definition of the respective lateral and vertical dopant profile in the first and second transistors 310A, 310B. As shown, a spacer structure 307 may be formed adjacent to the offset spacers 307A in order to provide a respective implantation mask so as to incorporate an appropriate dopant species into the first transistor 310A for defining deep drain and source portions 304. Furthermore, the device 300 is subjected to the anneal process 308C, which may be performed on the basis of process parameters so as to substantially avoid undue damage, wherein a corresponding critical parameter value for at least one process parameter may, for example, be different compared to the previously performed processes 308A, 308B due to the modified device configuration caused by the additional spacer structure 307. In other cases, an appropriately selected critical parameter value may be selected so as to result in appropriate process conditions for any of the processes 308A, 308B and 308C. Hence, the dopants in the regions 304 and 304E may be activated, wherein the portion 304E may have already experienced a plurality of activation processes, thereby increasing the degree of dopant activation and thus enhancing the sheet resistance, as is previously shown and explained with reference to FIG. 2d. Similarly, the process 308C may also enhance the degree of dopant activation in the extension region 304E of the second transistor 310B.

FIG. 3e schematically illustrates the semiconductor device 300 in a further advanced manufacturing stage, wherein deep drain and source portions 304 are also formed in the second transistor 310B, which are subsequently activated by a further radiation-based anneal process 308D. Consequently, during the process 308D, the degree of dopant activation in the first transistor 310A may be further enhanced, in particular in the extension region 304E thereof, while the activation may also be enhanced in the extension region 304E of the second transistor 310B and creating a desired degree of dopant activation in the deep drain and source portions 304 of the second transistor 310B. In further illustrative embodiments, one or more further radiation-based anneal processes may be performed, as previously explained with reference to the device 200, so as to even further enhance the degree of dopant activation in the first and second transistors 310A, 310B. In the embodiment described above, a respective radiation-based anneal process may be performed after each implantation process for defining the respective drain and source regions, wherein one type of transistor may be subjected to a respective anneal process more often compared to the other type. For instance, in the above-described embodiments, the first transistor 310A may have been subjected to the respective anneal processes more frequently than the transistor 310B, thereby providing a higher activation energy dose in the first transistor 310A, which may be advantageous when the respective dopant species may require increased activation energy dose compared to other dopant species, such as boron that may be used in the second transistor 310B. In other illustrative embodiments, one or more conventional anneal processes may be used in combination with the multiple sequential radiation-based processes so as to enhance crystallinity, diffusion control and the like, as previously explained. It should further be appreciated that, in sophisticated applications, a higher number of implantation processes may be required to obtain the required lateral and dopant profile, as is for instance shown in FIGS. 3a-3e. Thus, in these cases, a respective radiation-based anneal process may be performed after some or each of the respective implantation processes, as previously described.

Furthermore, in the embodiments described above, at least one critical process parameter value may be determined so as to avoid or at least substantially reduce the probability of causing damage in the respective gate electrodes during each individual radiation-based anneal process. Additionally, the surface topography and/or the material composition prior to performing a respective radiation-based anneal process may be modified so as to locally reduce the probability of creating radiation-induced damage. For instance, an appropriate material may be selectively applied on the gate electrodes in order to enhance the reflectivity and thus to reduce the energy absorption during the corresponding radiation-based anneal processes, thereby significantly relaxing any constraints with respect to determining critical parameter values for the respective anneal processes. For example, during the patterning of the respective gate electrodes, an appropriate “reflective” layer may be formed with respect to a wavelength or wavelength range to be used in the radiation-based anneal process, thereby locally “patterning” the optical response within individual transistor elements, thereby reducing the energy deposition into the gate electrode, while substantially maintaining the energy deposition into the respective device areas not covered by the corresponding reflective layer. For example, a layer stack of silicon dioxide, silicon nitride, silicon oxynitride and the like may be designed so as to exhibit a high degree of reflectivity for the wavelength range under consideration, substantially without negatively affecting the respective patterning process for forming the gate electrodes and for forming other device components.

As a result, the present disclosure is directed to an improved technique for annealing doped areas of semiconductor devices, such as drain and source regions, wherein multiple radiation-based anneal processes are performed such that, during each individual anneal process, a reduced probability for creating damage in sensitive device areas is obtained. Thus, the positive effect of enhancing dopant activation may be accumulated while substantially avoiding the risk of inducing device damage, such as melting of gate areas, as is typically encountered in conventional high density radiation-based anneal techniques. The multiple radiation-based anneal processes may be incorporated into the overall manufacturing flow at any appropriate stage, wherein, in some illustrative embodiments, respective transistor elements may experience a respective anneal process more frequently than other transistors, thereby also contributing to a balance between the different activation energies of respective dopant species.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
annealing drain and source regions of a first transistor provided on a substrate by performing a first radiation-based anneal process, said first radiation-based anneal process resulting in irradiating said drain and source regions for an irradiation time of less than approximately 0.1 seconds; and
annealing said drain and source regions of said first transistor by performing a second radiation-based anneal process, said second radiation-based anneal process resulting in irradiating said drain and source regions for a irradiation time of less than approximately 0.1 seconds.

2. The method of claim 1, further comprising annealing said drain and source regions of said first transistor by a third radiation-based anneal process, said third radiation-based anneal process resulting in irradiating said drain and source regions for an irradiation time of less than approximately 0.1 seconds.

3. The method of claim 1, further comprising forming said drain and source regions of said first transistor by introducing a dopant species prior to performing said first and second radiation-based anneal processes.

4. The method of claim 1, further comprising forming an extension region of said drain and source regions of the first transistor prior to performing said first radiation-based anneal process and performing said first radiation-based anneal process prior to forming deep drain and source portions in said first transistor.

5. The method of claim 4, further comprising forming an extension region of drain and source regions of a second transistor after performing said first radiation-based anneal process and annealing said extension region of the second transistor in said second radiation-based anneal process.

6. The method of claim 1, further comprising forming said drain and source regions of the first transistor by performing a plurality of implantation processes for introducing a dopant species, wherein said first radiation-based anneal process is performed after a first one of said plurality of implantation processes and said second radiation-based anneal process is performed after a second one of said plurality of implantation processes.

7. The method of claim 1, further comprising determining a critical process parameter value for a temperature determining process parameter of said first and second radiation-based anneal processes, said critical process parameter value determining a lower limit for causing damage to a gate electrode of said first transistor.

8. The method of claim 7, wherein said temperature determining parameter is controlled on the basis of said critical process parameter value during said first and second radiation-based anneal processes.

9. The method of claim 5, wherein said first transistor is an N-channel transistor and said second transistor is a P-channel transistor.

10. A method, comprising:
forming drain and source regions of a first transistor device by performing a plurality of implantation processes for incorporating a dopant species into said drain and source regions; and
activating said dopant species in said drain and source regions of the first transistor by performing a plurality of short radiation-based anneal processes.

11. The method of claim 10, wherein each of said plurality of radiation-based anneal processes is performed after performing each of said plurality of implantation processes.

12. The method of claim 10, wherein each of said plurality of radiation-based anneal processes is performed on the basis of process parameters selected to substantially not cause damage in a gate electrode of said first transistor.

13. The method of claim 10, wherein at least one of said plurality of radiation-based anneal processes is performed after an implantation process for forming extension regions in said drain and source regions of the first transistor and prior to performing a subsequent implantation process for forming deep drain and source portions.

14. The method of claim 13, wherein at least one of said plurality of radiation-based anneal processes is performed after each of said implantation processes for forming said drain and source regions of the first transistor.

15. The method of claim 10, further comprising performing an anneal process for annealing said drain and source regions of the first transistor at a temperature of about 800° C. or less.

16. The method of claim 10, further comprising forming drain and source regions of a second transistor on the basis of said plurality of implantation processes, wherein at least one of said radiation-based anneal processes is performed after forming an extension region of said second transistor and prior to forming deep drain and source portions of said second transistor.

17. The method of claim 16, wherein said first and second transistors are of different conductivity type.

18. The method of claim 17, wherein an extension region of said first transistor is formed prior to forming said extension region of said second transistor and wherein one of said radiation-based anneal processes is performed prior to forming the extension region of said second transistor.

19. A method, comprising:
forming an extension region of a first transistor above a substrate, said substrate comprising said first transistor and a second transistor;
annealing said first transistor by performing a first radiation-based anneal process;
forming an extension region of said second transistor after performing said first radiation-based anneal process; and
annealing said second transistor by performing a second radiation-based anneal process.

20. The method of claim 19, further comprising forming deep drain and source portions in said first and second transistors and performing at least one further radiation-based anneal process for activating said deep drain and source portions.
